(19) United States
(12) Patent Application Publication
(10) Pub. No.: US 2010/0084739 A1
(43) Pub. Date: Apr. 8, 2010

(54) Semiconductor device and method of manufacturing the same

(75) Inventor: Koujirou Matsui, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTREONICS CORPORATION, Kawasaki-shi (JP)

(21) Appl. No.: 12/591,783

(22) Filed: Dec. 1, 2009

(30) Foreign Application Priority Data
Mar. 12, 2008 (JP) 2008-309088

(51) Int. Cl. H01L 29/92; H01L 21/02

(52) U.S. Cl. 257/532; 438/396; 257/E21.011; 257/E29.343

(57) ABSTRACT

A semiconductor device includes a MIM capacitor that includes an insulating film and a first electrode and a second electrode which are formed in the same layer in the insulating film and are facing to each other with the insulating film interposed therebetween. The first electrode and the second electrode respectively include a first high aspect via and a second high aspect via which extend as long as a length, in a stacked direction of the substrate, of a via and an interconnect provided on the via so as to be connected to the via formed in another region. A first potential and a second potential are respectively supplied to the first electrode and the second electrode.

This application is based on Japanese patent application No. 2008-309088, the content of which is incorporated hereinto by reference.

### BACKGROUND

1. Technical Field

The present invention relates to a semiconductor device and a method of manufacturing the same, and more particularly, to a semiconductor device including a MIM capacitor and a method of manufacturing the same.

2. Related Art

In recent years, metal-insulator-metal (MIM) capacitors having a parasitic resistance and a parasitic capacitance significantly less than those of conventional MOS capacitors have been used as capacitor elements. In addition, a structure in which the MIM capacitor is incorporated into a logic device to form one chip has been developed. In order to achieve the structure, it is necessary to integrate the structures and the manufacturing processes of the two devices. In the logic device, a multi-layer interconnect structure has been generally used. In the multi-layer interconnect structure, achieving the appropriate structure or process for the MIM capacitor is an important technical issue. In order to achieve the appropriate structure or process, a process which manufactures the electrodes of the MIM capacitor by the same method as that of forming the multi-layer interconnect structure in a device region has been developed.

Japanese Unexamined Patent Publication No. 2006-261455 discloses the structure of a MIM capacitor having a comb-shaped electrode. In addition, Japanese PCT National Publication No. 2003-536271 discloses an array capacitor structure in which capacitance is formed between conductive vias.

However, the present inventor has found that the semiconductor device disclosed in Japanese Unexamined Patent Publication No. 2006-261455 or Japanese PCT National Publication No. 2003-536271 has the following problems, which will be described with reference to FIG. 10 and FIGS. 11A to 11D.

As shown in FIG. 10, a semiconductor device 10 includes a MIM capacitor 12. The MIM capacitor 12 includes a plurality of first upper electrode interconnects 22 and a plurality of second upper electrode interconnects 32 that are alternately arranged. One end of each of the plurality of first upper electrode interconnects 22 is connected to a first potential supply interconnect 26. The first potential supply interconnect 26 and the plurality of first upper electrode interconnects 22 have a comb shape having the first upper electrode interconnects 22 as comb teeth. One end of each of the plurality of second upper electrode interconnects 32 is connected to a second potential supply interconnect 36. The second potential supply interconnect 36 and the plurality of second upper electrode interconnects 32 have a comb shape having the second upper electrode interconnects 32 as comb teeth.

FIGS. 11A to 11D are cross-sectional views illustrating a process of manufacturing the first upper electrode interconnects 22 and the second upper electrode interconnects 32 of the MIM capacitor 12 using a via-first dual damascene process. FIGS. 11A to 11D are cross-sectional views taken along the line C-C′ of FIG. 10. The semiconductor device 10 includes an insulating layer 50, an etching stop film 52, and an insulating film 54 formed on a substrate (not shown). First lower electrode interconnects 24 and second lower electrode interconnects 34 are formed in the insulating layer 50.

First, a plurality of via holes 60 is formed in the insulating film 54 (FIG. 11A). Then, a resist layer 70 for forming interconnect trenches is formed on the insulating film 54 (FIG. 11B). Openings 66 for forming interconnect trenches are formed in the resist layer 70 at positions corresponding to the first upper electrode interconnects 22, the second upper electrode interconnects 32, the first potential supply interconnect 26, and the second potential supply interconnect 36 of the MIM capacitor 12. However, in this case, the openings 66 for forming interconnect trenches are likely to deviate from the via holes 60 due to misalignment. In this case, interconnect trenches 64 are formed so as to deviate from the via holes 60 (FIG. 11C). In FIG. 11C, for comparison, the interconnect trenches 64 that do not deviate from the via holes 60 are represented by dashed lines. When the interconnect trenches 64 are formed so as not to deviate from the via holes 60, the distance between adjacent interconnect trenches is d3. On the other hand, when the interconnect trenches 64 are formed so as to deviate from the via holes 60, the width of the interconnect trench is increased by a value corresponding to the degree of deviation from the via hole 60, and the distance between adjacent interconnect trenches becomes d2 (d2<d3). Then, the interconnect trenches 64 and the via holes 60 are filled with a conductive material to form first vias 20, the first upper electrode interconnects 22, second vias 30, the second upper electrode interconnects 32, the first potential supply interconnect 26, and the second potential supply interconnect 36 (FIG. 11D).

However, when the interconnect trenches 64 are formed so as to deviate from the via holes 60, the width of the first upper electrode interconnect 22 and the widths of the second upper electrode interconnect 32 become more than the design values, and the distance between the first upper electrode interconnect 22 and the second upper electrode interconnect 32 becomes d2, which is less than the design value d3, as shown in FIG. 11D. As a result, the capacitance value of the MIM capacitor 12 is different from the design value and it is difficult to provide a stable capacitance value.

### SUMMARY

In one embodiment, there is provided a semiconductor device including: a substrate; a MIM capacitor that includes an insulating film formed over the substrate and a first electrode and a second electrode which are formed in the same layer in the insulating film and are facing to each other with the insulating film interposed therebetween, the first electrode and the second electrode respectively including a first high aspect via and a second high aspect via which extend as long as a length, in a stacked direction of the substrate, of a via and an interconnect provided on the via so as to be connected to the via formed in another region; a first potential supply interconnect that is formed in the insulating film so as to be electrically connected to the first electrode and supplies a first potential to the first electrode; and a second potential supply interconnect that is formed in the insulating film so as to be electrically connected to the second electrode and supplies a second potential to the second electrode.

In another embodiment, there is provided a method of manufacturing a semiconductor device, including: forming a dual damascene interconnect trench using a via-first dual damascene process which includes forming a via hole in an insulating film and forming interconnect trench that communicate with the via hole in the insulating film; and filling the dual damascene interconnect trench with a conductive material to form a dual damascene interconnect after the forming the dual damascene interconnect trench, wherein in the forming the via hole in the forming the dual damascene interconnect trench, a first via hole and a second via hole are formed, in the forming the interconnect trench in the forming the dual damascene interconnect trench, the interconnect trench is formed with at least a part of the first via hole and at least a part of the second via hole being covered with a resist layer, and in the forming the dual damascene interconnect, the first via hole and the second via hole are filled with the conductive material to form a MIM capacitor including a first electrode formed by filling the at least a part of the first via hole with the conductive material, a second electrode formed by filling the at least a part of the second via hole with the conductive material, and the insulating film.

According to the above-mentioned structure, the electrodes of the MIM capacitor is formed by the first high aspect via and the second high aspect via. Therefore, it is possible to prevent misalignment when the interconnects are formed on the vias. In this way, it is possible to maintain a constant distance between the electrodes and make the capacitance value of the MIM capacitor equal to the design value. As a result, it is possible to provide a stable capacitance value. In addition, it is possible to prevent a time dependent dielectric breakdown (TDDB) lifetime from being reduced.

The invention also includes any combination of the above-mentioned components and any method and apparatus using the invention.

According to the present invention, it is possible to provide a semiconductor device including a MIM capacitor with a stable capacitance value.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan view illustrating an example of the structure of a semiconductor device according to an embodiment of the invention;

FIGS. 2A and 2B are cross-sectional views illustrating an example of the structure of the semiconductor device according to the embodiment of the invention;

FIGS. 3A to 3C are cross-sectional views illustrating a method of manufacturing the semiconductor device according to the embodiment of the invention;

FIGS. 4A and 4B are plan views illustrating a process of manufacturing the semiconductor device according to the embodiment of the invention;

FIG. 5 is a cross-sectional view illustrating another example of the structure of the semiconductor device according to the embodiment of the invention;

FIG. 6 is a cross-sectional view illustrating still another example of the structure of the semiconductor device according to the embodiment of the invention;

FIG. 7 is a cross-sectional view illustrating yet another example of the structure of the semiconductor device according to the embodiment of the invention;

FIGS. 8A and 8B are plan views illustrating still yet another example of the structure of the semiconductor device according to the embodiment of the invention;

FIG. 9 is a cross-sectional view illustrating yet still another example of the structure of the semiconductor device according to the embodiment of the invention;

FIG. 10 is a diagram illustrating the problems when the electrodes of the MIM capacitor is formed by the dual damascene structure; and

FIGS. 11A to 11D are diagrams illustrating the problems when the electrodes of the MIM capacitor is formed by the dual damascene structure.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, exemplary embodiments of the invention will be described with reference to the accompanying drawings. In the drawings, the same components are denoted by the same reference numerals and description thereof will not be repeated.

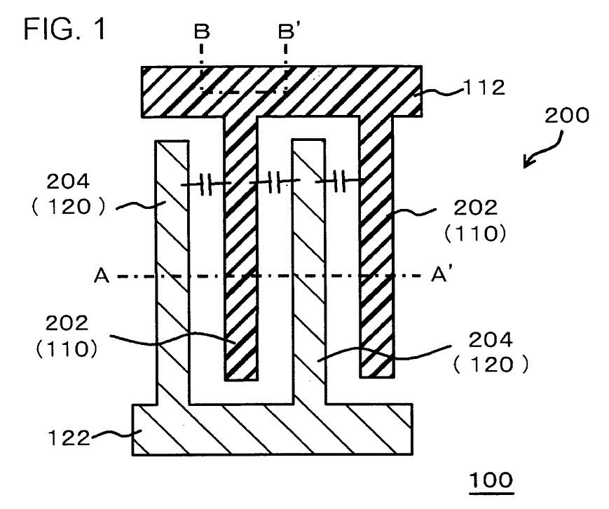

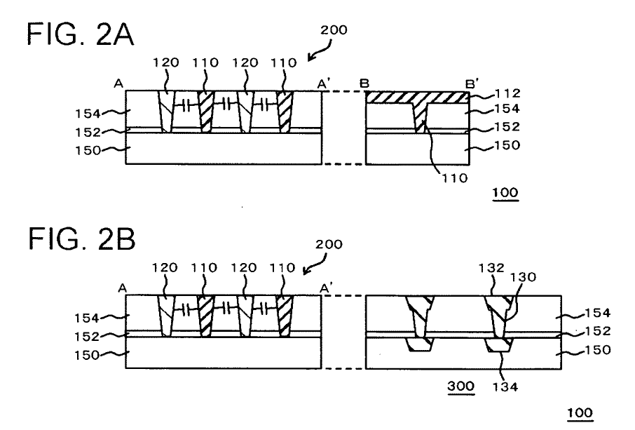

FIG. 1 is a plan view illustrating the structure of a semiconductor device according to an embodiment of the invention. FIGS. 2A and 2B are cross-sectional views illustrating the semiconductor device according to this embodiment. FIG. 2A is a cross-sectional view taken along the lines A-A′ and B-B′ of FIG. 1. FIG. 2B shows a cross section taken along the line A-A′ of FIG. 1 and another region 300 of a semiconductor device 100.

The semiconductor device 100 includes a substrate (not shown), an insulating layer 150, an etching stop film 152, and an insulating film 154 that are formed on the substrate, and a MIM capacitor 200 that is formed on the substrate. The MIM capacitor 200 includes a first electrode 202, a second electrode 204, and a capacitance film, which is an insulating film, interposed therebetween. The insulating layer 150, the etching stop film 152, and the insulating film 154 may be made of, for example, the same materials as that forming an insulating film or an etching stop film used in a multi-layer interconnect structure such as in a logic region. The insulating layer 150 and the insulating film 154 may be, for example, silicon oxide films or low dielectric films.

In this embodiment, the first electrode 202 and the second electrode 204 are formed in the same layer and respectively have first high aspect vias 110 and second high aspect vias 120 that are facing to each other with the insulating film 154 interposed therebetween.

In the region 300, lower interconnects 134 are formed in the insulating layer 150 and vias 130 are formed in the insulating film 154 and the etching stop film 152. In addition, upper interconnects 132 are formed in the insulating film 154. The vias 130 and the upper interconnects 132 may be dual damascene interconnects formed by a dual damascene process. The region 300 may be, for example, a peripheral circuit that is arranged in the vicinity of a region in which the MIM capacitor 200 is formed, or a logic region including a transistor and a multi-layer interconnect structure formed on the transistor. In this embodiment, the interconnects and the vias of the MIM capacitor 200 may be formed in the same process as that of forming the interconnects or the vias of the multi-layer interconnect structure of the region 300. For example, the interconnect or the via may include an interconnect material having copper as a main component and a barrier metal film that is formed on the side wall and the bottom of the interconnect material. In addition, the region 300 may be a region in which a first potential supply interconnect 112 and a second potential supply interconnect 122 are formed, when the first potential supply interconnect 112 and the second potential supply interconnect 122 are formed in the same layer as the first high aspect vias 110 and the second high aspect vias 120, as will be described below.

Each of the first high aspect vias 110 and the second high aspect vias 120 extends as long as a total length of the via 130 and the upper interconnect 132 (interconnect) formed in the region 300, in the stacked direction of the substrate. In addition, each of the first high aspect vias 110 and the second high aspect vias 120 is a slit via that extends in a first direction (the longitudinal direction in FIG. 1) when seen in a plan view.

The semiconductor device 100 further includes the first potential supply interconnect 112 that is formed in the insulating film 154 so as to be electrically connected to the first high aspect vias 110 and supplies a first potential to the first high aspect vias 110, and the second potential supply interconnect 122 that is formed in the insulating film 154 so as to be electrically connected to the second high aspect vias 120 and supplies a second potential to the second high aspect vias 120.

As shown in FIG. 1, the MIM capacitor 200 includes a plurality of the first high aspect vias 110 and a plurality of the second high aspect vias 120, which are slit vias extending in the first direction (the longitudinal direction in FIG. 1). The first high aspect vias 110 and the second high aspect vias 120 are alternately arranged in a second direction (the lateral direction in FIG. 1) orthogonal to the first direction. When seen in a plan view, the first potential supply interconnect 112 is formed at the ends of the first high aspect vias 110 so as to extend in the second direction, and the first potential supply interconnect 112 and the plurality of first high aspect vias 110 have a comb shape having the plurality of first high aspect vias 110 as comb teeth. In addition, when seen in a plan view, the second potential supply interconnect 122 is formed at the ends of the second high aspect vias 120 so as to extend in the second direction, and the second potential supply interconnect 122 and the plurality of second high aspect vias 120 have a comb shape having the plurality of first high aspect vias 110 as comb teeth. In this embodiment, in the MIM capacitor 200, the comb shape formed by the first potential supply interconnect 112 and the first high aspect vias 110 and the comb shape formed by the second potential supply interconnect 122 and the second high aspect vias 120 are arranged in a nested shape. One of the first potential and the second potential may be a ground potential, and the other potential may be a power supply potential.

As shown in FIGS. 2A and 2B, in this embodiment, the first potential supply interconnect 112 is provided at the same level as the upper interconnects 132 formed in the region 300, in the stacked direction of the substrate. At the same time, the first potential supply interconnect 112 is provided at an upper part of the first high aspect via 110, in the stacked direction of the substrate. In addition, in this embodiment, the second potential supply interconnect 122 is provided at the same level as the first potential supply interconnect 112 in the stacked direction of the substrate. That is, in this embodiment, the first high aspect vias 110, the second high aspect vias 120, the first potential supply interconnect 112, and the second potential supply interconnect 122 are formed by the same via-first dual damascene process. The first high aspect vias 110 and the second high aspect vias 120 are provided by forming only the via holes without forming the interconnect trenches in the via-first dual damascene process.

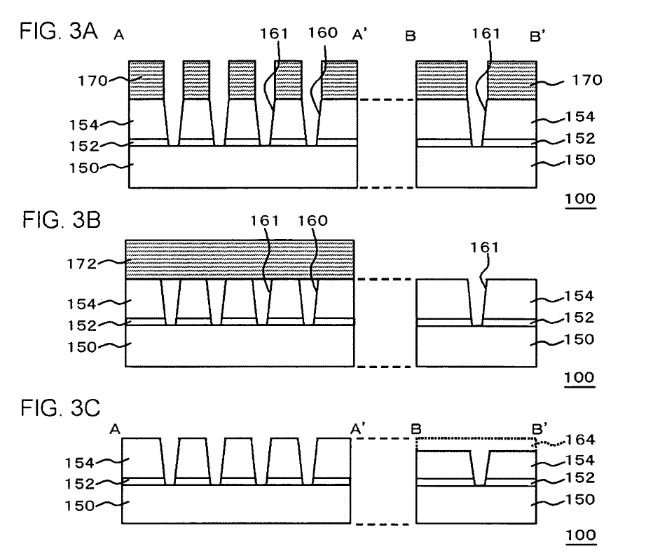

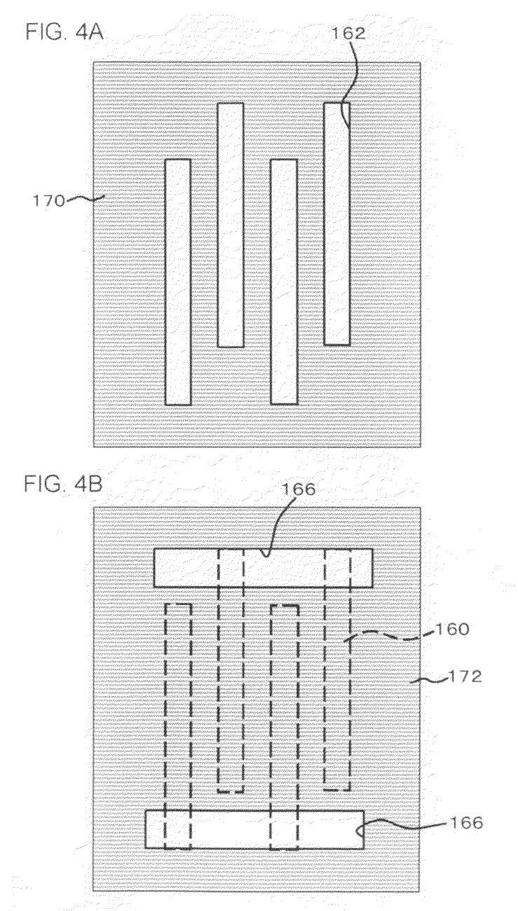

Next, a method of manufacturing the MIM capacitor 200 of the semiconductor device 100 according to this embodiment will be described. FIGS. 3A to 3C are cross-sectional views illustrating a process of manufacturing the semiconductor device 100 according to this embodiment. FIGS. 3A to 3C are cross-sectional views illustrating the same section of the semiconductor device 100 as shown in FIG. 2A. FIGS. 4A and 4B are plan views illustrating the process of manufacturing the semiconductor device 100 according to this embodiment.

In this embodiment, a method of manufacturing the semiconductor device 100 includes a process of forming dual damascene interconnect trenches using the via-first dual damascene process and a process of filling the dual damascene interconnect trenches with a conductive material to form dual damascene interconnects after the process of forming the dual damascene interconnect trenches. The process of forming the dual damascene interconnect trenches includes a process of forming via holes in the insulating film 154 and a process of forming interconnect trenches that communicate with the via holes in the insulating film 154.

First, a resist layer 170 for forming via holes is formed on the insulating film 154, and the insulating film 154 is etched using the resist layer 170 as a mask to form first via holes 160 and second via holes 161 in the insulating film 154. FIG. 4A shows the structure of the resist layer 170 for forming via holes that is used to form the via holes 160 in the insulating film 154. Openings 162 for forming via holes are formed in the resist layer 170 at positions corresponding to the first high aspect vias 110 and the second high aspect vias 120 of the MIM capacitor 200.

FIG. 3A shows the first via holes 160 and the second via holes 161 formed in the insulating film 154. The first via holes 160 and the second via holes 161 are formed so as to extend across the layer in which the via holes and the interconnect trenches of the dual damascene interconnect trenches are formed. In this case, although not shown in the drawings, the via holes for forming the vias 130 of the region 300 that has been described with reference to FIG. 2B are also formed.

Then, a resist layer 172 for forming interconnect trenches is formed on the insulating film 154. FIG. 4B shows the structure of the resist layer 172 for forming interconnect trenches that is used to form the interconnect trenches 164 in the insulating film 154. Openings 166 for forming interconnect trenches are formed in the resist layer 172 at positions corresponding to the first potential supply interconnect 112 and the second potential supply interconnect 122 of the semiconductor device 100. In this case, a portion of the first via hole 160 other than the edge thereof and a portion of the second via hole 161 other than the edge thereof are covered with the resist layer 172 for forming interconnect trenches. The insulating film 154 is etched using the resist layer 172 as a mask to form the interconnect trenches 164 in the insulating film 154. In this case, although not shown in the drawings, the interconnect trench for forming the second potential supply interconnect 122 and the interconnect trenches for forming the upper interconnects 132 of the region 300 that has been described with reference to FIG. 2B are also formed.

Then, the via holes, such as the first via holes 160 and the second via holes 161, and the interconnect trenches, such as the interconnect trenches 164, are filled with a conductive material. The conductive material may be filled by the same method as that forming the interconnects in a general dual damascene process. First, a barrier metal film is formed, and the via holes and the interconnect trenches are filled with an interconnect material. Then, the conductive material exposed from the via holes and the interconnect trenches are removed by a chemical mechanical polishing (CMP) method. In this way, as shown in FIGS. 2A and 2B, the first high aspect vias 110, the second high aspect vias 120, and the first potential supply interconnect 112 are formed. At the same time, the second potential supply interconnect 122, and the vias 130 and the upper interconnects 132 of the region 300 are also formed.

In this embodiment, the first high aspect vias 110 and the second high aspect vias 120 of the MIM capacitor 200 are provided without forming the interconnect trenches in the process of forming the dual damascene interconnect trenches using the via-first dual damascene process. Therefore, it is possible to prevent misalignment when the interconnects are formed on the vias. In this way, it is possible to maintain a constant distance between the electrodes and make the capacitance value of the MIM capacitor 200 equal to the design value. As a result, it is possible to provide a stable capacitance value. In addition, it is possible to prevent a time dependent dielectric breakdown (TDDB) lifetime from being reduced.

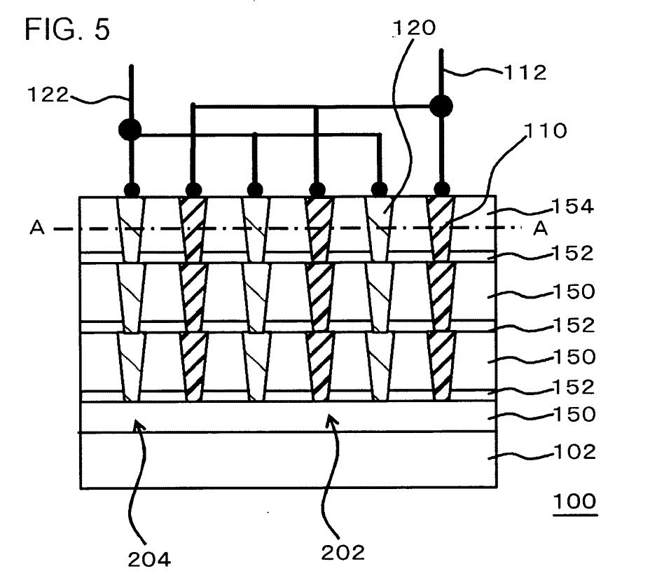

FIG. 5 is a diagram illustrating a modification of the structure of the MIM capacitor 200 shown in FIG. 1 and FIGS. 2A and 2B.

In this modification, the first electrode 202 and the second electrode 204 may be formed so as to extend across a plurality of layers.

For example, in this modification, the first electrode 202 may include the first high aspect vias 110 that are formed in three layers. In addition, the second electrode 204 may include the second high aspect vias 120 that are formed in three layers. The first potential supply interconnect 112 may be provided only in the same layer as the uppermost first high aspect vias 110. The second potential supply interconnect 122 may be provided only in the same layer as the uppermost second high aspect vias 120. Alternatively, the first potential supply interconnect 112 and the second potential supply interconnect 122 may be provided in different layers.

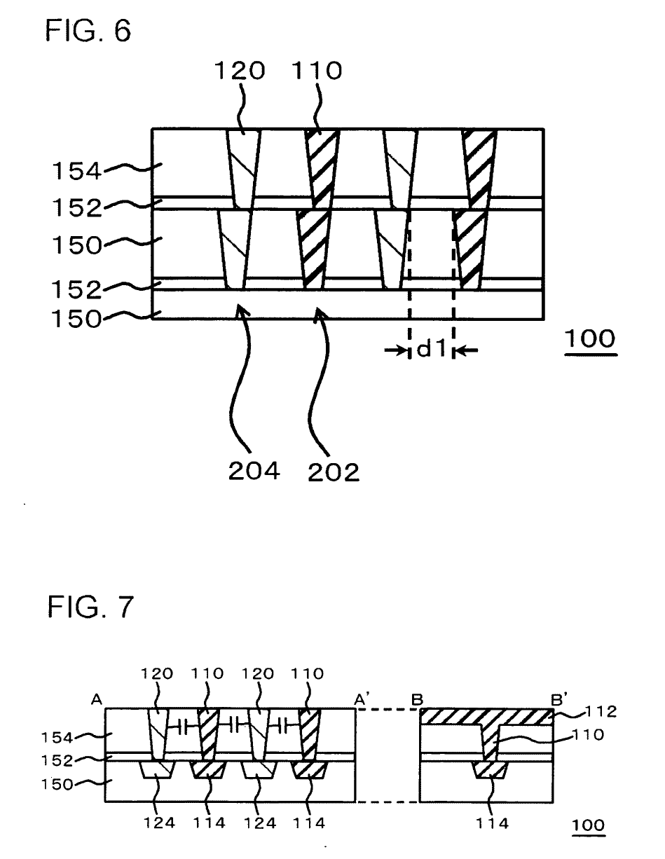

According to the above-mentioned stacked structure, a misalignment between the upper and lower vias may occur. FIG. 6 is a diagram illustrating the case in which misalignment between the upper and lower vias occurs. Each of the first high aspect vias 110 and the second high aspect vias 120 has a tapered shape in a cross-sectional view in which the diameter of the via is reduced toward the lower side. Therefore, when the bottom of the upper via does not deviate from the upper surface of the lower via, it is possible to maintain a constant distance d1 between the first high aspect via 110 and the second high aspect via 120 adjacent to each other. In this way, it is possible to prevent influence on the capacitance value and pressure resistance. Even when the bottom of the upper via deviates from the upper surface of the lower via, the etching stop film 152 is disposed so as to control the overall thickness of the upper via and the lower via that overlap each other from to be smaller than the thickness of the etching stop film 152. Therefore, it is possible to significantly reduce the influence on the capacitance value and pressure resistance.

FIG. 7 is a diagram illustrating another example of the semiconductor device 100 shown in FIG. 1.

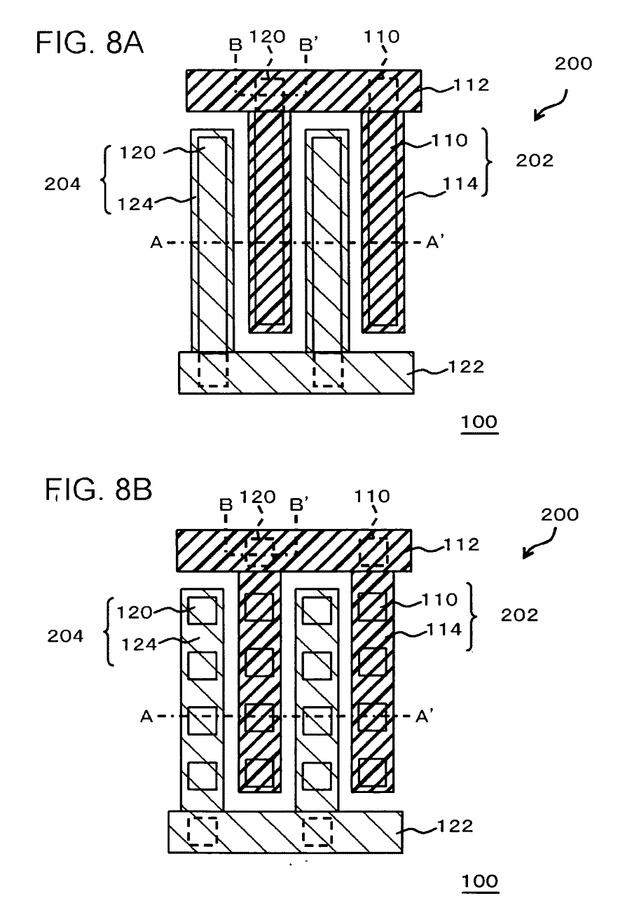

In this example, first electrode interconnects 114 and second electrode interconnects 124 are provided below the first high aspect vias 110 and the second high aspect vias 120, respectively. FIGS. 8A and 8B are plan views of FIG. 7. FIG. 7 is a cross-sectional view taken along the line A-A′ and the line B-B′ of FIGS. 8A and 8B. FIG. 8A shows an example in which the first high aspect via 110 and the second high aspect via 120 are slit vias.

Each of the first electrode interconnects 114 is provided so as to come into contact with the first high aspect via 110, and extends in the first direction. Each of the second electrode interconnects 124 is provided so as to come into contact with the second high aspect via 120, and extends in the first direction.

As such, when the electrode interconnects are provided in the lowest layer, the first high aspect vias 110 and the second high aspect vias 120 may be a plurality of vias that is arranged in the first direction, not the slit vias that are continuously formed in the first direction, as shown in FIG. 8B. That is, the first electrode 202 may include a plurality of first high aspect vias 110 that is arranged in the first direction and the first electrode interconnects 114 that are formed below the first high aspect vias 110. The second electrode 204 may include a plurality of second high aspect vias 120 that is arranged in the first direction and the second electrode interconnects 124 that are formed below the second high aspect vias 120.

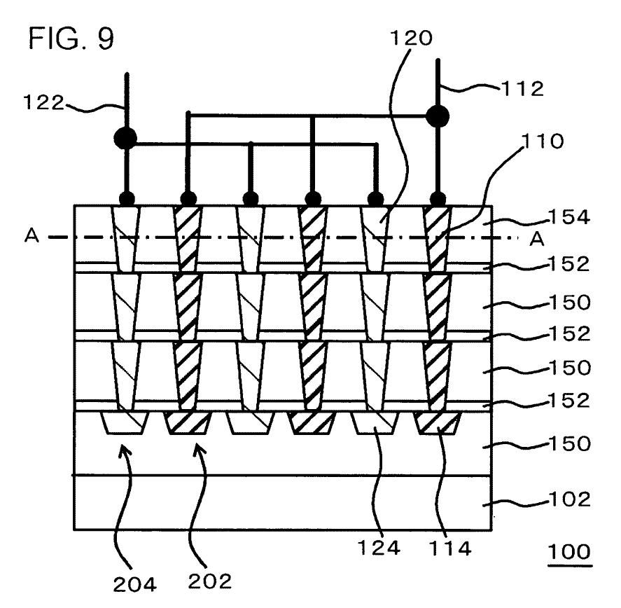

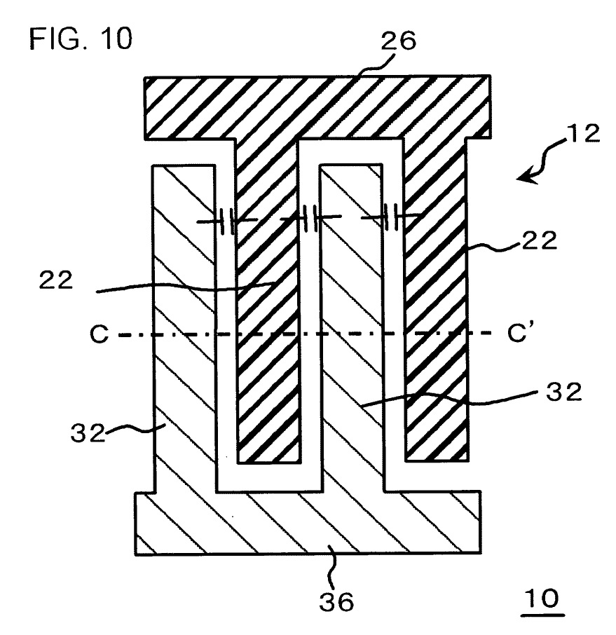

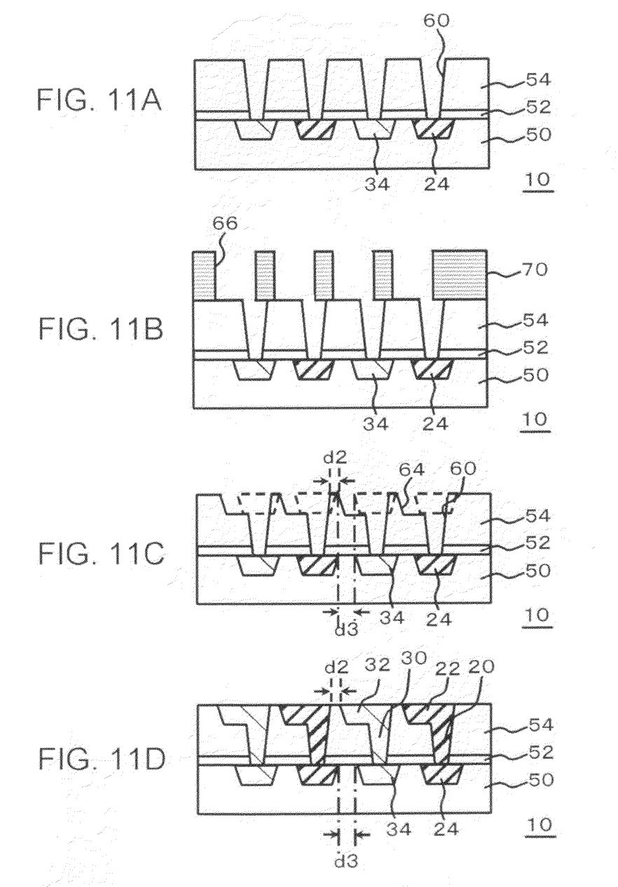

FIG. 9 is a diagram illustrating a modification of the MIM capacitor 200 shown in FIG. 7 and FIGS. 8A and 8B.

In this modification, similar to the structure shown in FIG. 5, the first electrode 202 and the second electrode 204 may be formed so as to be laid across a plurality of layers. The first electrode interconnects 114 and the second electrode interconnects 124 are provided below the lowest first high aspect vias 110 and the lowest second high aspect vias 120, respectively.

The embodiments of the invention have been described above with reference to the drawings. However, it is apparent that the present invention is not limited to the above embodiment, and may be modified and changed without departing from the scope and spirit of the invention.

What is claimed is:

1. A semiconductor device comprising:
a substrate;
a MIM capacitor that includes an insulating film formed over said substrate and a first electrode and a second electrode which are formed in the same layer in said insulating film and are facing to each other with said insulating film interposed therebetween, said first electrode and said second electrode respectively including a first high aspect via and a second high aspect via which extend as long as a length, in a stacked direction of said substrate, of a via and an interconnect provided on said via so as to be connected to said via formed in another region;
a first potential supply interconnect that is formed in said insulating film so as to be electrically connected to said first electrode and supplies a first potential to said first electrode; and
a second potential supply interconnect that is formed in said insulating film so as to be electrically connected to said second electrode and supplies a second potential to said second electrode.

2. The semiconductor device as set forth in claim 1, wherein said first potential supply interconnect is provided at the same level as a part of an upper portion of a region in which said first high aspect via extend in said stacked direction of said substrate and is connected to said first high aspect via.

3. The semiconductor device as set forth in claim 2, wherein said second potential supply interconnect is provided at the same level as that of said first potential supply interconnect in said stacked direction of said substrate and is connected to said second high aspect via.

4. The semiconductor device as set forth in claim 1,
wherein said MIM capacitor further includes:
a first electrode interconnect that is provided below said first high aspect via so as to come into contact with said first high aspect via, and extends in a first direction; and
a second electrode interconnect that is provided below said second high aspect via so as to come into contact with said second high aspect via, and extends in said first direction.

5. The semiconductor device as set forth in claim 1, wherein said first high aspect via and said second high aspect via are slit vias that extend in a first direction.

6. The semiconductor device as set forth in claim 4,
wherein said first electrode is formed with a plurality of said first high aspect vias, said plurality of first high aspect vias being arranged over said first electrode interconnect in said first direction, and
said second electrode is formed with a plurality of said second high aspect vias, said plurality of second high aspect vias being arranged over said second electrode interconnect in said first direction.

7. The semiconductor device as set forth in claim 1,
wherein said MIM capacitor includes a plurality of said first electrodes and a plurality of said second electrodes, respectively formed in the same layer and extending in a first direction, said plurality of first electrodes and said plurality of second electrodes are alternately arranged in a second direction orthogonal to said first direction,
said first potential supply interconnect is formed at the ends of said first electrodes so as to extend in said second direction so that said first potential supply interconnect and said plurality of first electrodes have a comb shape having said plurality of first electrodes as comb teeth when seen in a plan view, and
said second potential supply interconnect is formed at the ends of said second electrodes so as to extend in said second direction so that said second potential supply interconnect and said plurality of second electrodes have a comb shape having said plurality of second electrodes as comb teeth in a plan view.

8. The semiconductor device as set forth in claim 1,
wherein said first electrode includes a plurality of said first high aspect vias that is formed in a plurality of layers so as to be stacked to each other, and
said second electrode includes a plurality of said second high aspect vias that is formed in said plurality of layers so as to be stacked to each other.

9. The semiconductor device as set forth in claim 1, wherein said via and said interconnect provided on said via so as to be connected to said via formed in said another region have a dual damascene interconnect structure.

10. A method of manufacturing a semiconductor device, comprising:
forming a dual damascene interconnect trench using a via-first dual damascene process which includes forming a via hole in an insulating film and forming interconnect trench that communicate with said via hole in said insulating film; and
filling said dual damascene interconnect trench with a conductive material to form a dual damascene interconnect after said forming the dual damascene interconnect trench,
wherein in said forming the via hole in said forming the dual damascene interconnect trench, a first via hole and a second via hole are formed,
in said forming the interconnect trench in said forming the dual damascene interconnect trench, said interconnect trench is formed with at least a part of said first via hole and at least a part of said second via hole being covered with a resist layer, and
in said forming the dual damascene interconnect, said first via hole and said second via hole are-filled with said conductive material to form a MIM capacitor including a first electrode formed by filling said at least a part of said first via hole with said conductive material, a second electrode formed by filling said at least a part of said second via hole with said conductive material, and said insulating film.
